(19) United States
(12) Patent Application Publication
(10) Pub. No.: US 2026/0223418 A1
(43) Pub. Date: Jul. 30, 2026

(54) SWITCHING ELEMENT AND MANUFACTURING METHOD THEREOF

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventor: Ryota SUZUKI, Nisshin-shi (JP)

(21) Appl. No.: 19/422,594

(22) Filed: Dec. 17, 2025

(30) Foreign Application Priority Data
Jan. 29, 2025 (JP) 2025-013091

(51) Int. Cl. H10D 62/10; H10D 30/01; H10D 30/66; H10D 62/00; H10D 62/832; H10D 64/00

(52) U.S. Cl. CPC H10D 62/111; H10D 30/0297; H10D 30/668; H10D 62/054; H10D 62/8325; H10D 64/117

(57) ABSTRACT

A switching element includes: a semiconductor substrate having dummy trenches extending in a first direction; a gate insulating film in contact with an element region between the dummy trenches; a gate electrode; and a source electrode in contact with the element region. The semiconductor substrate has: a source region arranged in the element region; a body region arranged in the element region; a drift region distributed from the element region to below the dummy trenches; an intermediate region extending linearly within the drift region in a second direction intersecting the first direction; and connection regions respectively located adjacent to the dummy trenches to connect the intermediate region to the source electrode.

### CROSS REFERENCE TO RELATED APPLICATION

This application is based on Japanese Patent Application No. 2025-013091 filed on January 29, 2025, the disclosure of which is incorporated herein by reference.

### TECHNICAL FIELD

The technology disclosed in this specification relates to a switching element and a manufacturing method thereof.

### BACKGROUND

There is a gate-type switching element such as MOSFET (Metal-Oxide-Semiconductor Field Effect Transistor), IGBT (Insulated Gate Bipolar Transistor), and the like.

### SUMMARY

According to an aspect of the present disclosure, a switching element includes: a semiconductor substrate having a plurality of dummy trenches extending in a first direction on an upper surface, the plurality of dummy trenches being arranged at interval in a direction perpendicular to the first direction; a gate insulating film in contact with an element region of the semiconductor substrate between the plurality of dummy trenches; a gate electrode in contact with the gate insulating film and insulated from the semiconductor substrate by the gate insulating film; and a source electrode in contact with the element region. The semiconductor substrate includes: a source region of a first conductivity type located in the element region and in contact with the source electrode and the gate insulating film; a body region of a second conductivity type located in the element region and in contact with the source region and the gate insulating film; and a drift region distributed from within the element region to below each of the plurality of dummy trenches and in contact with the body region and the gate insulating film within the element region. The semiconductor substrate may further include: a plurality of intermediate regions of a second conductivity type extending linearly within the drift region in a second direction intersecting the first direction and arranged at interval in a direction perpendicular to the second direction, a lower end of each of the plurality of intermediate regions being located lower than a lower end of each of the plurality of dummy trenches; and a plurality of connection regions of a second conductivity type respectively located adjacent to the plurality of dummy trenches to connect the plurality of intermediate regions to the source electrode.

### BRIEF DESCRIPTION OF DRAWINGS

FIG. 1 is a perspective view of a switching element according to a first embodiment.

FIG. 2 is a perspective view of the switching element of the first embodiment in which a source electrode is omitted.

FIG. 3 is a perspective view illustrating a modification of the first embodiment in which a source electrode is omitted.

FIG. 4 is a perspective view illustrating a modification of the first embodiment in which a source electrode is omitted.

FIG. 5 is a perspective view illustrating a modification of the first embodiment in which a source electrode is omitted.

FIG. 6 is a perspective view of a switching element according to a second embodiment in which a source electrode is omitted.

FIG. 7 is a perspective view illustrating a modification of the second embodiment in which a source electrode is omitted.

FIG. 8 is a perspective view of a switching element according to a third embodiment in which a source electrode is omitted.

FIG. 9 is a perspective view illustrating a modification of the third embodiment in which a source electrode is omitted.

FIG. 10 is an explanatory diagram illustrating a method for manufacturing the switching element of the third embodiment.

FIG. 11 is an explanatory diagram illustrating a method for manufacturing the switching element of the third embodiment.

FIG. 12 is an explanatory diagram illustrating a method for manufacturing the switching element of the third embodiment.

FIG. 13 is an explanatory diagram illustrating a method for manufacturing the switching element of the third embodiment.

FIG. 14 is an explanatory diagram illustrating a method for manufacturing the switching element of the third embodiment.

FIG. 15 is an explanatory diagram of variations in trench arrangement pattern.

FIG. 16 is an explanatory diagram of variations in trench arrangement pattern.

FIG. 17 is an explanatory diagram of variations in trench arrangement pattern.

FIG. 18 is an explanatory diagram of variations in trench arrangement pattern.

FIG. 19 is a diagram illustrating a modification of an internal structure of a dummy trench.

FIG. 20 is a diagram illustrating a modification of a connection region.

FIG. 21 is a diagram illustrating a modification of a connection region.

FIG. 22 is a perspective view illustrating an embodiment of a planar switching element.

### DETAILED DESCRIPTION

When a switching element is turned off at high speed, a surge voltage occurs, and the surge voltage may generate an avalanche current in the drift region. The avalanche current flows through the semiconductor substrate to the source electrode. At this time, if an avalanche current flows near the gate, the heat generated by the avalanche current may deteriorate the gate insulating film. This specification proposes a technique for reducing the degradation of the gate insulating film when an avalanche current occurs.

According to an aspect of the present disclosure, a switching element includes: a semiconductor substrate having dummy trenches extending along a first direction on the upper surface and spaced apart in a direction perpendicular to the first direction; a gate insulating film in contact with an element region of the semiconductor substrate between the dummy trenches; a gate electrode in contact with the gate insulating film and insulated from the semiconductor substrate by the gate insulating film; and a source electrode in contact with the element region. The semiconductor substrate has a source region, a body region, a drift region, an intermediate region, and plural connection regions. The source region is a first conductivity type region disposed in the element region and in contact with the source electrode and the gate insulating film. The body region is a second conductivity type region disposed within the element region and in contact with the source region and the gate insulating film. The drift region is distributed from within the element region to below the dummy trenches, and in contact with the body region and the gate insulating film within the element region. The intermediate region extends linearly within the drift region along a second direction that intersects the first direction. The intermediate regions are second conductivity type regions spaced apart in a direction perpendicular to the second direction. The intermediate regions are arranged such that lower ends of the intermediate regions are located lower than lower ends of the dummy trenches. The connection region is a second conductivity type region adjacent to the dummy trench and connects the intermediate region to the source electrode.

In this specification, one of the first conductivity type and the second conductivity type means n-type, and the other means p-type.

In this specification, the drift region is a region through which a current flows when a switching element is on and which is depleted when the switching element is off.

In this switching element, the intermediate region of second conductivity type is provided in the drift region. The intermediate region of second conductivity type is connected to the source electrode by the connection region, so that the intermediate region of second conductivity type has substantially the same potential as the source electrode. Therefore, when an avalanche current occurs in the drift region, the avalanche current flows into the intermediate region of second conductivity type. The avalanche current that has flowed into the intermediate region of second conductivity type flows to the source electrode via the connection region. Furthermore, since the connection region is located adjacent to the dummy trench arranged on both ends of the element region, the connection region is arranged at position away from the gate insulating film. Therefore, even if the connection region generates heat due to the flow of avalanche current, the heat is not easily transferred to the gate insulating film. Therefore, the deterioration of the gate insulating film can be restricted.

### First Embodiment

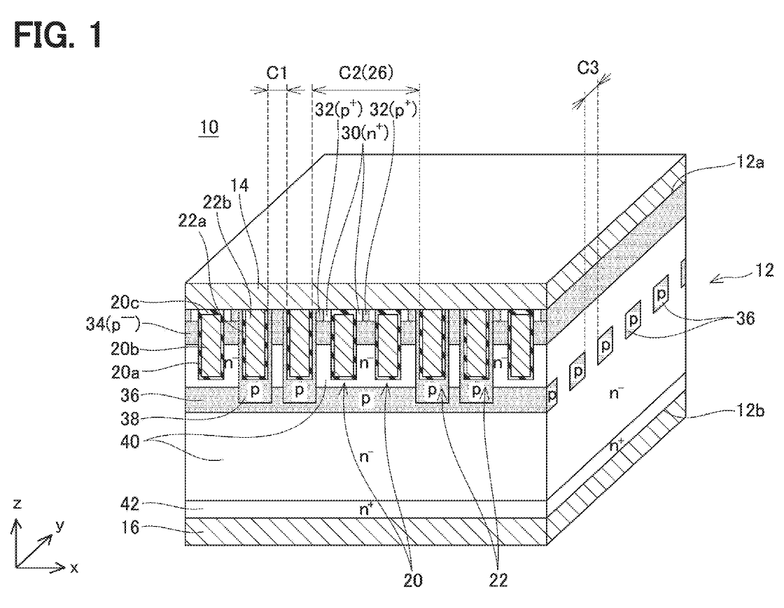

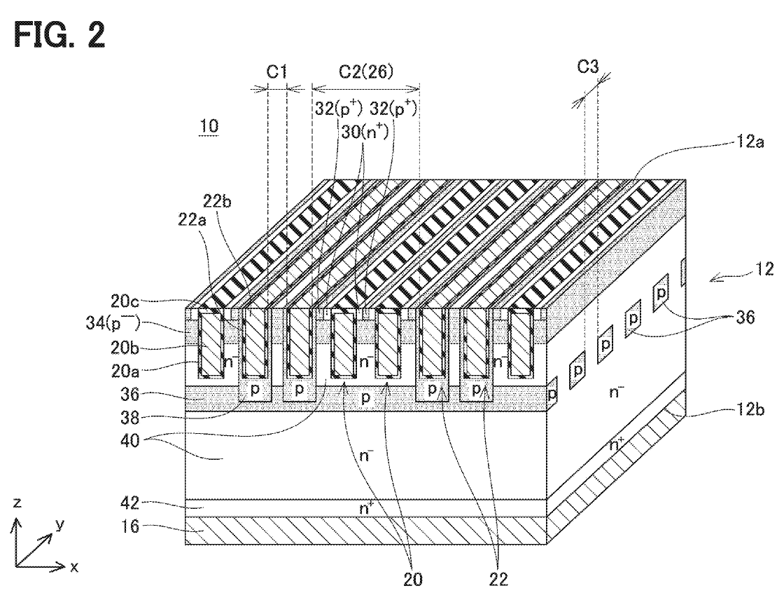

A switching element 10 of a first embodiment shown in FIGS. 1 and 2 is a MOSFET. The switching element 10 includes a semiconductor substrate 12, a source electrode 14, and a drain electrode 16. In FIG. 2, illustration of the source electrode 14 is omitted. The semiconductor substrate 12 is made of SiC. The semiconductor substrate 12 may be made of other semiconductor materials such as Si or GaN. As shown in FIG. 1, the source electrode 14 covers the upper surface 12a of the semiconductor substrate 12. As shown in FIGS. 1 and 2, the drain electrode 16 covers the lower surface 12b of the semiconductor substrate 12. Hereinafter, the thickness direction of the semiconductor substrate 12 is referred to as z direction. One direction in a plane perpendicular to the z direction is referred to as x direction, and a direction perpendicular to the x direction in the plane is referred to as y direction.

Gate trenches 20 and dummy trenches 22 are provided on the upper surface 12a of the semiconductor substrate 12. The gate trench 20 functions as the gate of the MOSFET. A channel is formed along the side surface of the gate trench 20 when the MOSFET is turned on. The dummy trench 22 does not function as the gate of the MOSFET, and no channel is formed when the MOSFET is turned on. Each of the gate trench 20 and the dummy trench 22 extends linearly along the y direction on the upper surface 12a. The depth of the gate trench 20 is approximately equal to the depth of the dummy trench 22.

The dummy trenches 22 are arranged at interval in the x direction. At some positions, a clearance C1 is provided between the dummy trenches 22 in the x direction. At other positions, a clearance C2 is provided between the dummy trenches 22 in the x direction. The clearance C2 is longer than the clearance C1. The dummy trenches 22 are arranged in the x direction so that the clearance C1 and the clearance C2 are alternately provided. Hereinafter, a portion of the semiconductor substrate 12 located between the two dummy trenches 22 spaced apart by the clearance C2 will be referred to as an element region 26. Each of the gate trenches 20 is disposed within the element region 26. Plural (two in this embodiment) gate trenches 20 are arranged in each of the element regions 26. Therefore, two dummy trenches 22 and two gate trenches 20 are alternately arranged repeatedly in the x direction.

In each of the gate trenches 20, a gate insulating film 20a and a gate electrode 20b are provided. The gate insulating film 20a covers the inner surface of the gate trench 20. The gate electrode 20b is disposed at a position surrounded by the gate insulating film 20a. The gate electrode 20b is insulated from the semiconductor substrate 12 by the gate insulating film 20a. The upper surface of the gate electrode 20b is covered with an interlayer insulating film 20c. The gate electrode 20b is insulated from the source electrode 14 by the interlayer insulating film 20c. Each of the gate electrodes 20b is connected to a gate pad provided at a position (not shown). The potential of the gate electrode 20b is controlled by the gate pad.

An insulating film 22a and a dummy electrode 22b are provided in each of the dummy trenches 22. The insulating film 22a covers the inner surface of the dummy trench 22. The dummy electrode 22b is disposed at a position surrounded by the insulating film 22a. No interlayer insulating film is provided on the upper surface of the dummy electrode 22b, and the dummy electrode 22b is connected to the source electrode 14 on the upper surface. The dummy electrode 22b is insulated from the gate electrode 20b. Therefore, the potential of the gate electrode 20b is controlled independently of the potential of the dummy electrode 22b.

The semiconductor substrate 12 has n-type source regions 30, plural p-type contact regions 32, a p-type body region 34, plural intermediate p-type regions 36, plural p-type connection regions 38, an n-type drift region 40, and an n-type drain region 42.

The source region 30 is an n-type region having a high n-type impurity concentration. The source region 30 is provided in the element region 26. The source region 30 is provided in an area between two gate trenches 20 and an area between the gate trench 20 and the dummy trench 22. The source region 30 is disposed in an area including the upper surface 12a of the semiconductor substrate 12 and is in ohmic contact with the source electrode 14. The source region 30 is in contact with the gate insulating film 20a at the upper end of the side surface of the gate trench 20. Each of the source regions 30 extends linearly in the y direction.

The contact region 32 is a p-type region having a high p-type impurity concentration. The contact region 32 is provided in the element region 26. The contact region 32 is provided in an area between two gate trenches 20 and an area between the gate trench 20 and the dummy trench 22. The contact region 32 is disposed adjacent to the source region 30. The contact region 32 is disposed in an area including the upper surface 12a of the semiconductor substrate 12 and is in ohmic contact with the source electrode 14. Each of the contact regions 32 extends linearly in the y direction. The contact region 32 may also be provided in an area between the two dummy trenches 22.

The body region 34 is a p-type region having a lower p-type impurity concentration than the contact region 32. The body region 34 is distributed across an area between the two gate trenches 20, an area between the gate trench 20 and the dummy trench 22, and an area between the two dummy trenches 22. The body region 34 is in contact with the source region 30 and the contact region 32 from below within the element region 26. The body region 34 is connected to the source electrode 14 via the contact region 32. The body region 34 is in contact with the gate insulating film 20a below the source region 30.

The drift region 40 is a region through which electrons flow when the switching element is on, and is depleted when the switching element is off. In this embodiment, the drift region 40 is an n-type region having a lower n-type impurity concentration than the source region 30. The drift region 40 is distributed across an area between the trenches (i.e., between the two gate trenches 20, between the gate trench 20 and the dummy trench 22, and between the two dummy trenches 22). The drift region 40 is distributed from the area between the trenches to below the lower ends of the gate trench 20 and the dummy trench 22. The drift region 40 is distributed from the area between the trenches to a position near the lower surface 12b of the semiconductor substrate 12. The drift region 40 is in contact with the body region 34 from below within the element region 26. The drift region 40 is separated from the source region 30 by the body region 34. The drift region 40 is in contact with the gate insulating film 20a below the body region 34.

The intermediate p-type region 36 is a p-type region having a p-type impurity concentration lower than that of the contact region 32 and higher than that of the body region 34. Each of the intermediate p-type regions 36 extends linearly in the x direction inside the drift region 40. The intermediate p-type regions 36 are arranged with a clearance C3 in the y direction. The drift region 40 is distributed within the clearance C3. In other words, the drift region 40 is distributed from the upper side to the lower side of the intermediate p-type region 36 via the clearance C3. The intermediate p-type region 36 is in contact with the drift region 40 on the top, bottom, and side surfaces. The intermediate p-type region 36 is disposed below the lower ends of the gate trench 20 and the dummy trench 22. That is, both the upper and lower ends of the intermediate p-type region 36 are located lower than the lower ends of the gate trench 20 and the dummy trench 22.

The connection region 38 is a p-type region having a p-type impurity concentration lower than that of the contact region 32 and higher than that of the body region 34. The connection region 38 is provided in an area adjacent to the corresponding dummy trench 22. More specifically, the connection region 38 is provided from an area adjacent to the side surface of the corresponding dummy trench 22 to an area adjacent to the bottom surface of the corresponding dummy trench 22. The connection region 38 extends linearly in the y direction along the corresponding dummy trench 22. The connection region 38 is in contact with the source electrode 14 at the upper end. The connection region 38 is in contact with each of the intermediate p-type regions 36 at the lower ends. Therefore, each of the intermediate p-type regions 36 is connected to the source electrode 14 via the connection region 38.

The drain region 42 is an n-type region having a higher n-type impurity concentration than the drift region 40. The drain region 42 is disposed below the drift region 40 and in contact with the drift region 40. The drain region 42 is in ohmic contact with the drain electrode 16 on the lower surface 12b of the semiconductor substrate 12.

The following describes the operation of the switching element 10. The switching element 10 is used in a state where a higher potential than that of the source electrode 14 is applied to the drain electrode 16. When a potential equal to or higher than the gate threshold is applied to the gate electrode 20b, a channel is formed in the body region 34 adjacent to the gate insulating film 20a. That is, the channel is formed in the body region 34 within the element region 26. The channel connects the source region 30 and the drift region 40. As a result, electrons flow from the source electrode 14 through the source region 30 and the channel into the drift region 40. Within the drift region 40, electrons flow from the top of the intermediate p-type region 36 through the clearance C3 to the bottom of the intermediate p-type region 36. The electrons that flow through the drift region 40 to the bottom end flow to the drain electrode 16 via the drain region 42. This flow of electrons causes a current to flow from the drain electrode 16 to the source electrode 14. That is, the switching element 10 is turned on.

When the potential of the gate electrode 20b is reduced to a potential below the gate threshold, the channel disappears and the current stops. That is, the switching element 10 is turned off. When the switching element 10 is turned off, the potential of the drift region 40 rises. Since the body region 34 has approximately the same potential as the source electrode 14, when the potential of the drift region 40 rises, a reverse voltage is applied to the pn junction at the interface between the body region 34 and the drift region 40. As a result, a depletion layer spreads from the body region 34 to the drift region 40. Furthermore, since the intermediate p-type region 36 is connected to the source electrode 14 via the connection region 38, the intermediate p-type region 36 has approximately the same potential as the source electrode 14. Therefore, when the potential of the drift region 40 rises, a reverse voltage is also applied to the pn junction at the interface between the intermediate p-type region 36 and the drift region 40. Therefore, the depletion layer spreads from the intermediate p-type region 36 to the drift region 40. In this way, when the switching element 10 is turned off, a depletion layer spreads from the body region 34 and the intermediate p-type region 36 to the drift region 40. The depletion layer extends from the intermediate p-type region 36 to the drift region 40, thereby restricting the electric field generated at the bottom end of the gate trench 20. Since the intermediate p-type region 36 has approximately the same potential as the source electrode 14, the electric field generated at the bottom end of the gate trench 20 is effectively restricted. This restricts electric field concentration on the gate insulating film 20a covering the lower end of the gate trench 20.

Furthermore, in the switching element 10, since the intermediate p-type region 36 is provided below the gate electrode 20b, the capacitance is reduced between the gate electrode 20b and the drain electrode 16 (i.e., feedback capacitance). Therefore, the switching element 10 can perform switching at high speed.

Furthermore, when the switching element 10 is turned off, the current flowing through the switching element 10 decreases rapidly, and a high surge voltage is applied to the switching element 10. This can create a high electric field within the drift region 40, causing an avalanche current. The avalanche current flows from the drift region 40 to the source electrode 14. If an avalanche current flows near the gate insulating film 20a, the gate insulating film 20a may be exposed to high temperatures and deteriorated. Furthermore, if an avalanche current flows near the gate insulating film 20a, hot carriers may be trapped in the gate insulating film 20a, causing fluctuations in the gate threshold. However, in this embodiment, as will be described below, the intermediate p-type region 36 and the connection region 38 prevent the avalanche current from flowing near the gate insulating film 20a. As described above, in this embodiment, the intermediate p-type region 36 has approximately the same potential as the source electrode 14. Therefore, when an avalanche current occurs in the drift region 40, the avalanche current flows into the intermediate p-type region 36. The avalanche current that has flowed into the intermediate p-type region 36 flows to the source electrode 14 via the connection region 38. As shown in FIGS. 1 and 2, the connection regions 38 are provided on both ends of the element region 26 and are located at positions separated from the gate insulating film 20a. That is, the avalanche current flows to the source electrode 14 through a position away from the gate insulating film 20a. Therefore, in this embodiment, the deterioration of the gate insulating film 20a due to the avalanche current is restricted.

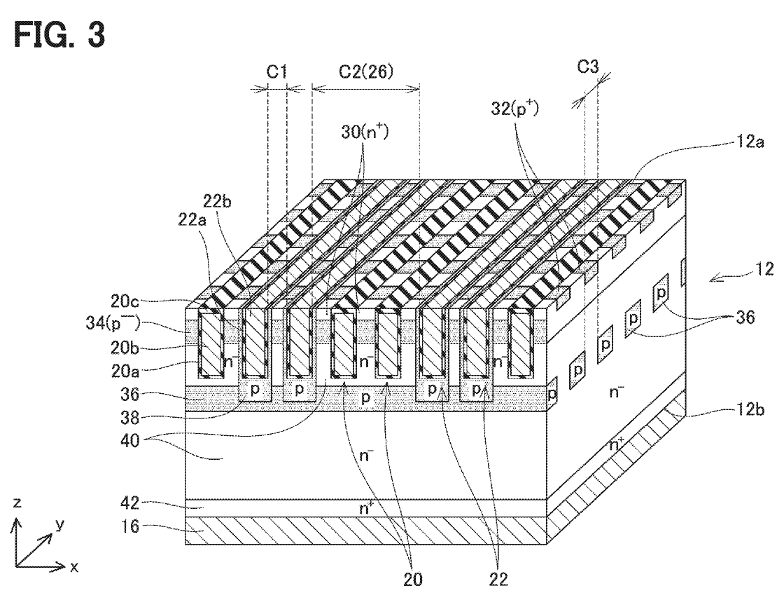

In the first embodiment, the contact region 32 extends linearly in the y direction (i.e., parallel to each of the trenches). However, as illustrated in FIG. 3, the contact region 32 may extend linearly along a direction intersecting the trenches. The angle at which the contact region 32 intersects with the trench may be 90 degrees or may be another angle.

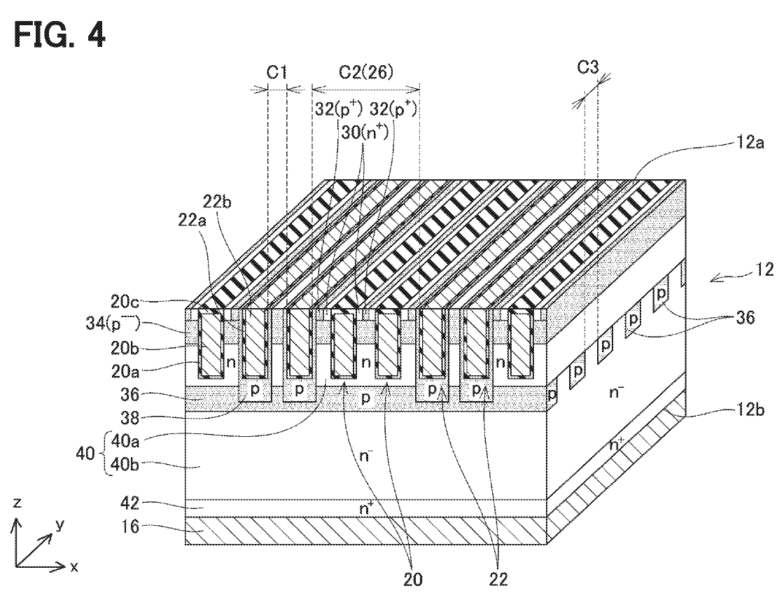

In the first embodiment, the drift region 40 has a substantially constant n-type impurity concentration. However, as shown in FIG. 4, a drift region 40a above the intermediate p-type region 36 may have a higher n-type impurity concentration than a drift region 40b below the intermediate p-type region 36. According to this configuration, the resistance of the drift region 40 can be reduced in the area between the trenches (where the current path is narrow). Thus, the on-resistance of the switching element can be reduced.

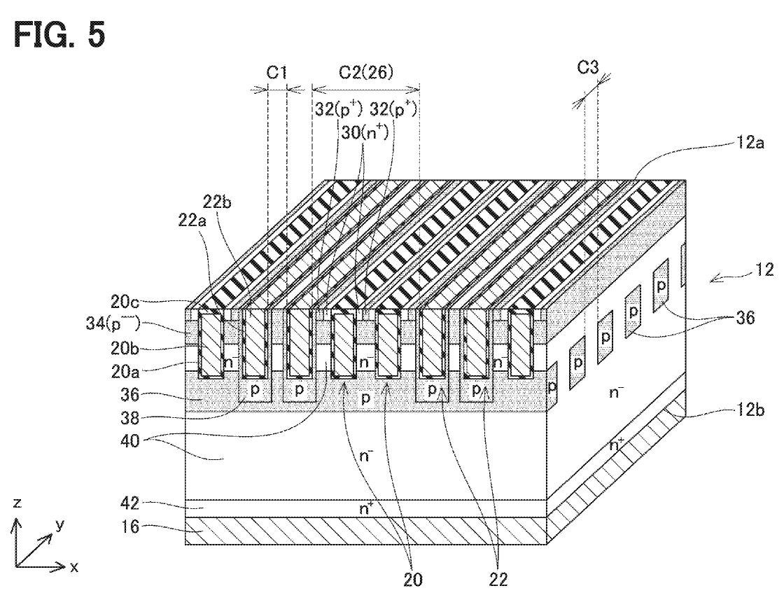

In the first embodiment, the upper end of the intermediate p-type region 36 is located lower than the lower end of the trench 20, 22. However, as shown in FIG. 5, the upper end of the intermediate p-type region 36 may be located above the lower end of the trench 20, 22. That is, the intermediate p-type region 36 may be disposed at a position that overlaps with the lower end of the trench 20, 22 in the z direction.

The configurations of FIGS. 3, 4 and 5 may be combined with other embodiments described later.

### Second Embodiment

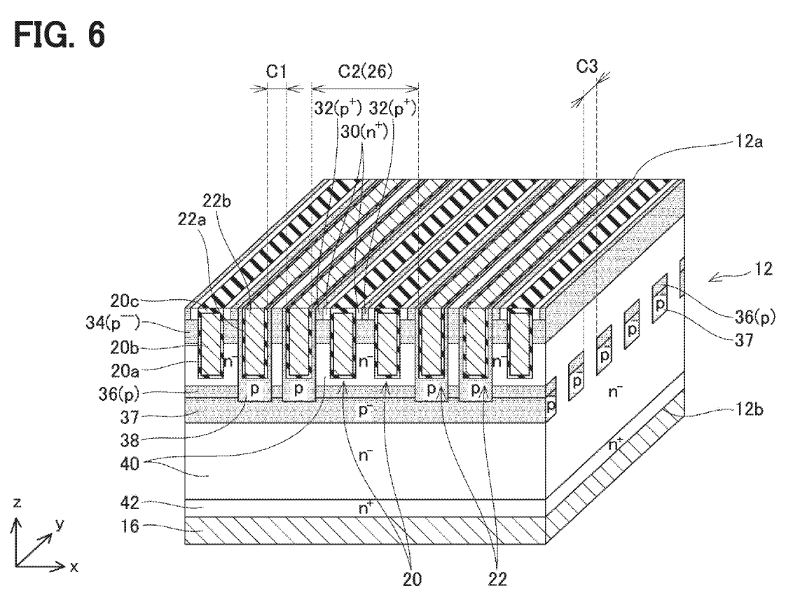

A switching element of a second embodiment shown in FIG. 6 has low-concentration intermediate p-type regions 37. Each of the low-concentration intermediate p-type regions 37 is a p-type region having a lower p-type impurity concentration than the intermediate p-type region 36 and the connection region 38. The low-concentration intermediate p-type region 37 is provided below the corresponding intermediate p-type region 36. The low-concentration intermediate p-type region 37 extends linearly in the x direction along the intermediate p-type region 36. The low-concentration intermediate p-type region 37 is in contact with the corresponding intermediate p-type region 36 from below. The low-concentration intermediate p-type regions 37 are arranged with the clearance C3 in the y direction. The drift region 40 above the intermediate p-type region 36 is connected to the drift region 40 below the low-concentration intermediate p-type region 37 via the clearance C3. In the second embodiment, the connection region 38 extends from the upper surface 12a into the low-concentration intermediate p-type region 37. That is, the connection region 38 passes through the intermediate p-type region 36. The lower end of the connection region 38 is disposed inside the low-concentration intermediate p-type region 37. Except for the above points, the second embodiment is the same as the first embodiment.

When the switching element of the second embodiment is turned off, a depletion layer spreads in the low-concentration intermediate p-type region 37 where the p-type impurity concentration is low. Therefore, the withstand voltage of the switching element 10 is further improved.

In the second embodiment, the connection region 38 penetrates the intermediate p-type region 36 and extends into the low-concentration intermediate p-type region 37. Therefore, when the switching element is turned off, the low-concentration intermediate p-type region 37 near the bottom end of the connection region 38 is less likely to be depleted than the low-concentration intermediate p-type region 37 in other portions. Therefore, electric field concentration is likely to occur near the lower end of the connection region 38. When a high surge voltage is applied to the switching element due to turn-off, an avalanche breakdown occurs near the lower end of the connection region 38. Therefore, the avalanche current flows easily to the connection region 38, and the avalanche current can be more reliably prevented from flowing near the gate insulating film 20a. This makes it possible to more effectively restrict deterioration of the gate insulating film 20a.

Furthermore, since the connection region 38 has a relatively high p-type impurity concentration, the density of crystal defects in the connection region 38 is relatively high. If the connection region 38, which has a relatively high density of crystal defects, is depleted and an electric field is applied, a leakage current may occur. In contrast to this, in the second embodiment, the connection region 38 does not penetrate the low-concentration intermediate p-type region 37, and the lower end of the connection region 38 is located inside the low-concentration intermediate p-type region 37. Therefore, when the switching element is turned off, the depletion layer is prevented from expanding into the connection region 38. Therefore, the leakage current is restricted.

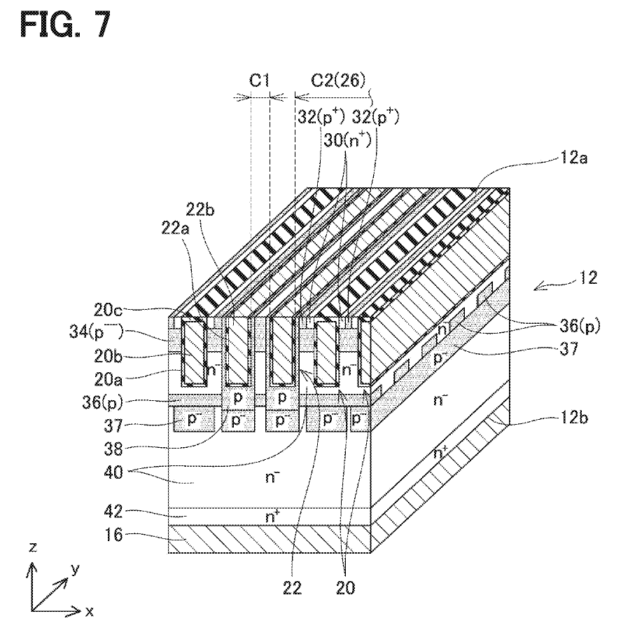

In the second embodiment, the low-concentration intermediate p-type region 37 extends linearly along the intermediate p-type region 36. However, as shown in FIG. 7, the low-concentration intermediate p-type region 37 may extend linearly along a direction intersecting with the intermediate p-type region 36. In this configuration, the intermediate p-type region 36 and the low-concentration intermediate p-type region 37 form a lattice-like p-type region. This configuration also improves the breakdown voltage of the switching element. The angle at which the low-concentration intermediate p-type region 37 intersects with the intermediate p-type region 36 may be 90 degrees or may be any other angle. In this way, while the intermediate p-type region 36 extends linearly along a direction intersecting the trench, the shape of the p-type region added to the intermediate p-type region 36 (i.e., the low-concentration intermediate p-type region 37, etc.) is not particularly limited.

### Third Embodiment

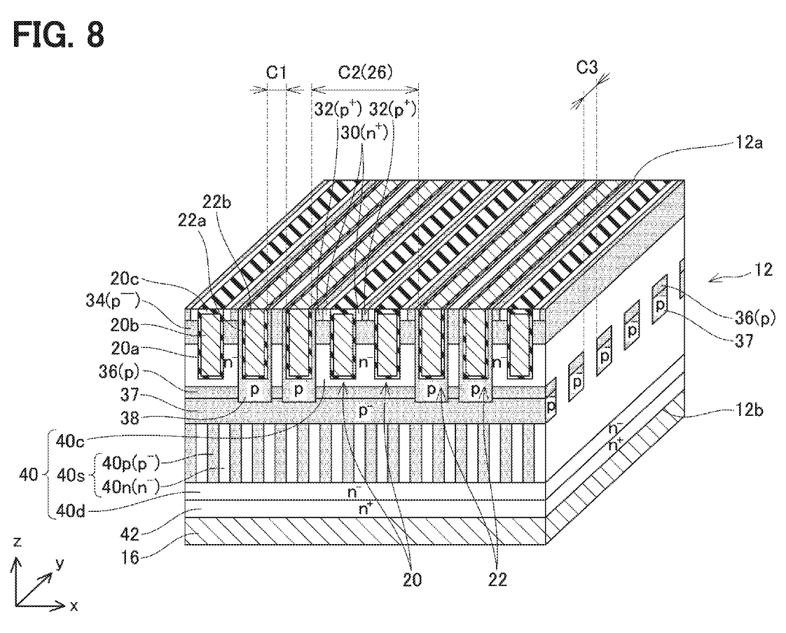

A switching element of a third embodiment shown in FIG. 8 has a drift region 40 with a different structure from that of the second embodiment. Except for the drift region 40, the third embodiment is identical to the second embodiment.

As shown in FIG. 8, in the third embodiment, the drift region 40 below the low-concentration intermediate p-type region 37 includes a superjunction layer 40s. The superjunction layer 40s has a superjunction structure in which p-type layers 40p and n-type layers 40n are alternately arranged in the x direction. The p-type layer 40p and the n-type layer 40n extend linearly in the y direction. The p-type layer 40p and the n-type layer 40n are in contact with the low-concentration intermediate p-type region 37 at the upper ends. Above the intermediate p-type region 36, the drift region 40 includes an n-type layer 40c. The n-type layer 40c has a relatively high n-type impurity concentration, similar to the drift region 40a in FIG. 4. The n-type layer 40c has a higher n-type impurity concentration than the n-type layer 40n. The n-type layer 40c may have a low n-type impurity concentration, similar to the drift region 40 in FIG. 2. In addition, within the clearance C3, the drift region 40 is formed by an n-type layer having a concentration as low as that of the n-type layer 40n. The drift region 40 below the superjunction layer 40s includes an n-type layer 40d having a low impurity concentration similar to that of the n-type layer 40n. The n-type layer 40d is in contact with the p-type layer 40p and the n-type layer 40n from below, and is in contact with the drain region 42 from above.

When the switching element of the third embodiment is turned off, a depletion layer spreads from each interface between the n-type layer 40n and the p-type layer 40p to the n-type layer 40n and the p-type layer 40p. Therefore, the superjunction layer 40s is easily depleted. Therefore, according to the third embodiment, the withstand voltage of the switching element can be further improved.

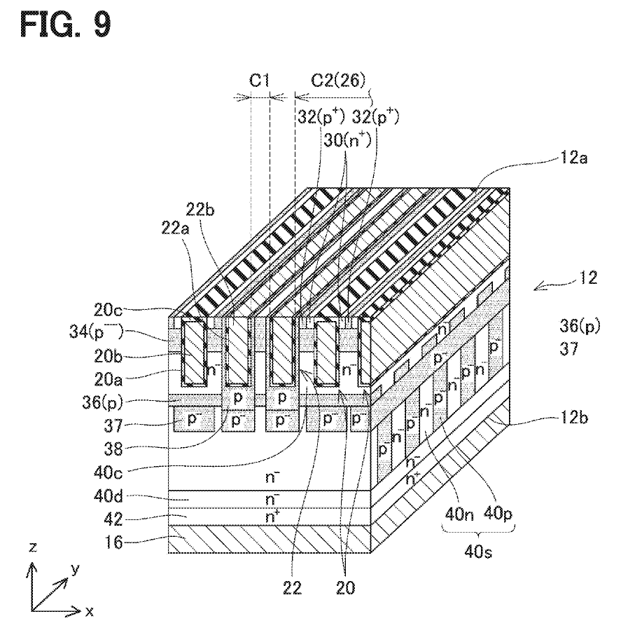

In the third embodiment, the p-type layers 40p and the n-type layers 40n are alternately arranged in the x direction, but as shown in FIG. 9, the p-type layers 40p and the n-type layers 40n may be alternately arranged in the y direction. Furthermore, the p-type layers 40p and the n-type layers 40n may be arranged alternately in other directions.

In the third embodiment, the p-type layer 40p and the n-type layer 40n are in contact with the low-concentration intermediate p-type region 37. However, when a superjunction layer is employed in a switching element that does not have a low-concentration intermediate p-type region 37 as shown in FIG. 2, for example, the p-type layer 40p and the n-type layer 40n may be in contact with the intermediate p-type region 36.

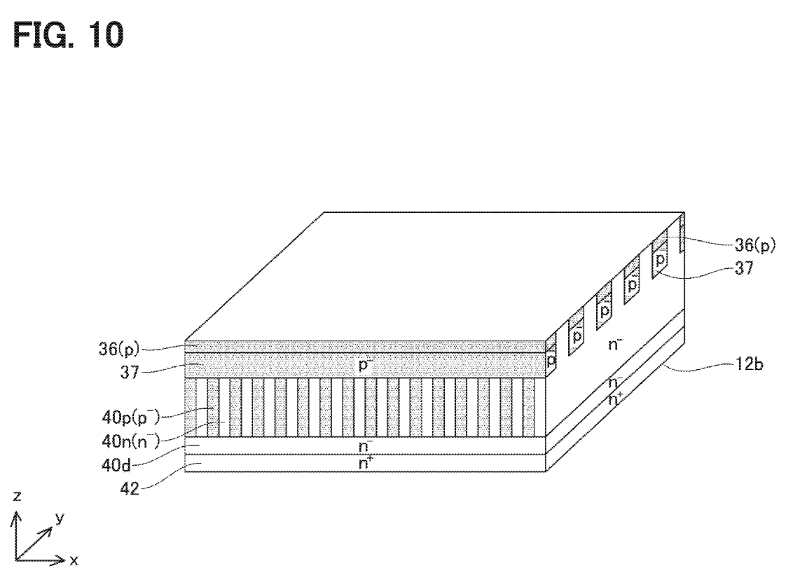

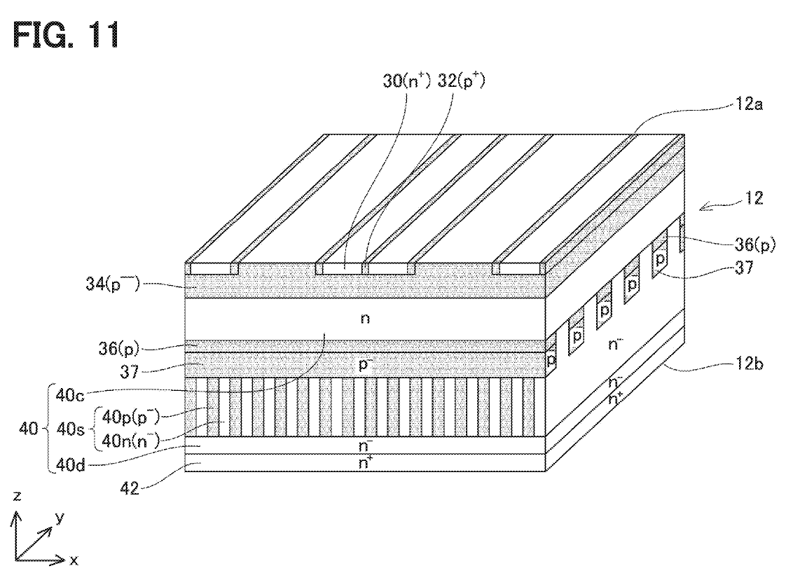

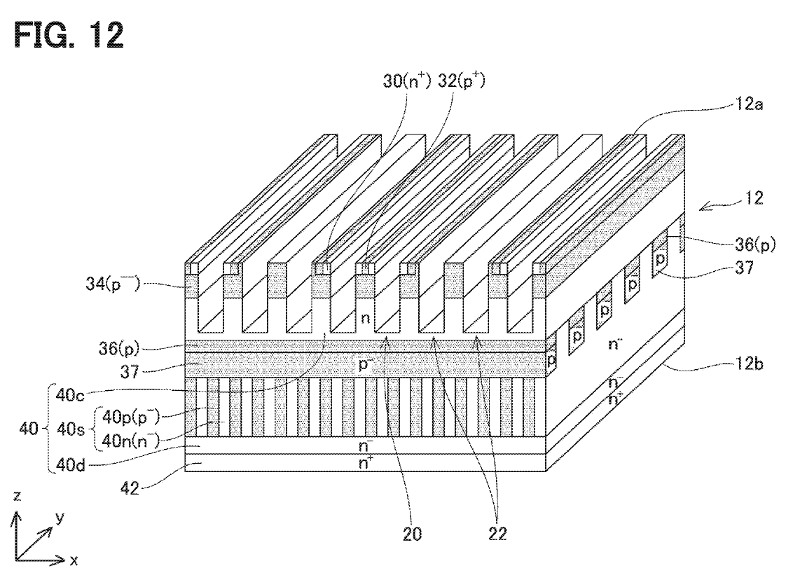

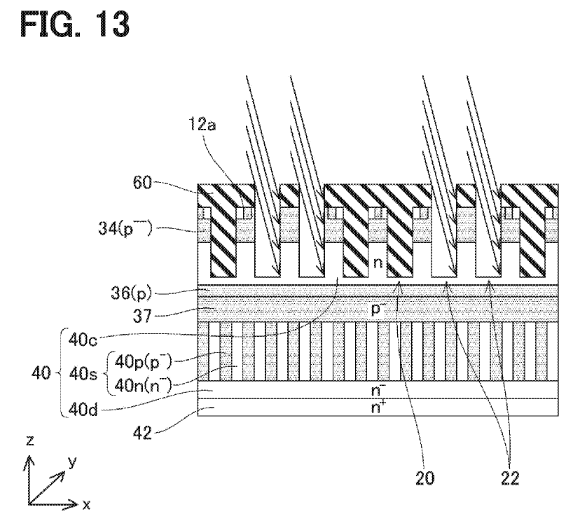

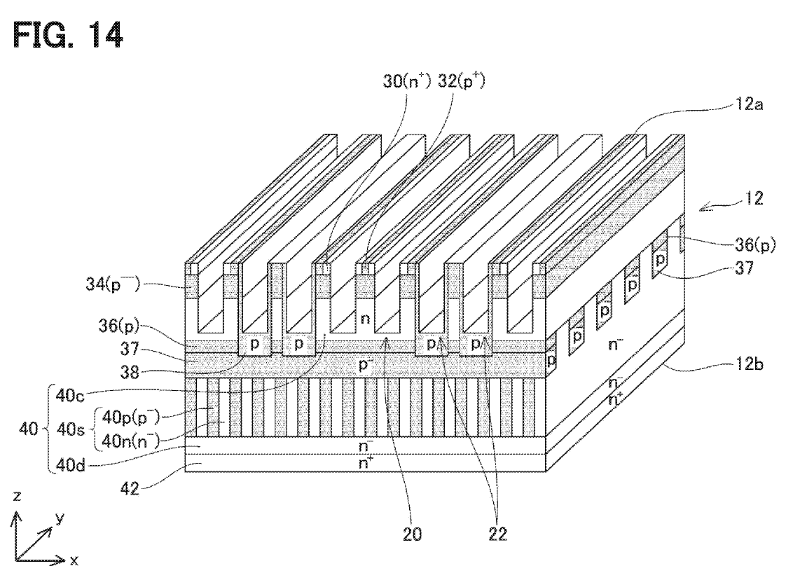

Next, a method for manufacturing the switching element will be described. Here, as an example, a method for manufacturing the switching element of the third embodiment will be described. First, the n-type layer 40d and the n-type layer 40n are epitaxially grown on the drain region 42. Next, as shown in FIG. 10, p-type impurities are implanted into the n-type layer 40n to form the p-type layer 40p, the low-concentration intermediate p-type region 37, and the intermediate p-type region 36. Next, as shown in FIG. 11, a low-concentration semiconductor layer is epitaxially grown on the semiconductor substrate 12, and ions are implanted into the semiconductor layer to form the n-type layer 40c, the body region 34, the contact region 32, and the source region 30. Next, as shown in FIG. 12, the upper surface 12a of the semiconductor substrate 12 is selectively etched to simultaneously form the gate trenches 20 and the dummy trenches 22 in the upper surface 12a. When the gate trench 20 and the dummy trench 22 are formed simultaneously in this manner, the depth of the gate trench 20 and the depth of the dummy trench 22 become approximately equal. Next, as shown in FIG. 13, with the upper surface 12a and the gate trench 20 covered with a mask 60, p-type impurities are ion-implanted into the dummy trench 22. Here, the p-type impurity is irradiated at an angle inclined with respect to the thickness direction of the semiconductor substrate 12, thereby implanting the p-type impurity into one side surface of the dummy trench 22. Similarly, p-type impurities are implanted into the other side surface of the dummy trench 22. Furthermore, p-type impurities are also implanted into the bottom surfaces of the dummy trenches 22. By implanting p-type impurities into the dummy trenches 22 in this manner, the connection regions 38 are formed as shown in FIG. 14. Next, the gate electrode 20b, the dummy electrode 22b, the source electrode 14, the drain electrode 16, etc. are formed to complete the switching element of the third embodiment shown in FIG. 8.

According to this manufacturing method, the gate trench 20 and the dummy trench 22 are formed simultaneously, so that the switching element can be manufactured efficiently. Furthermore, according to this manufacturing method, the connection region 38 is formed by ion implantation into the dummy trench 22, so that the connection region 38 can be formed with low implantation energy. Therefore, the connection region 38 can be formed by ion implantation in a short time, and the switching element can be manufactured efficiently. Furthermore, since the connection region 38 can be formed stably, variations in the characteristics of the switching elements can be restricted. The connection region 38 may be formed by a different method. For example, the connection region 38 may be formed by deep ion implantation into the upper surface 12a of the semiconductor substrate 12.

Modifications that can be adopted in the embodiments will be described below.

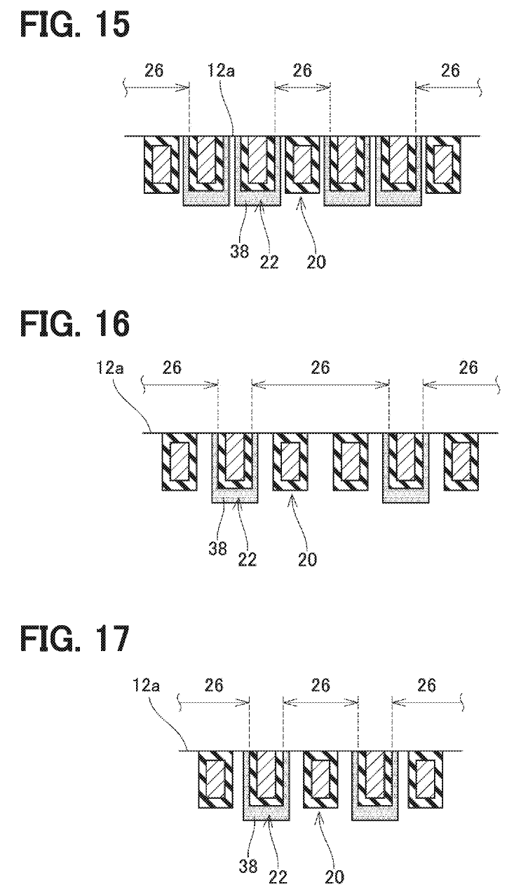

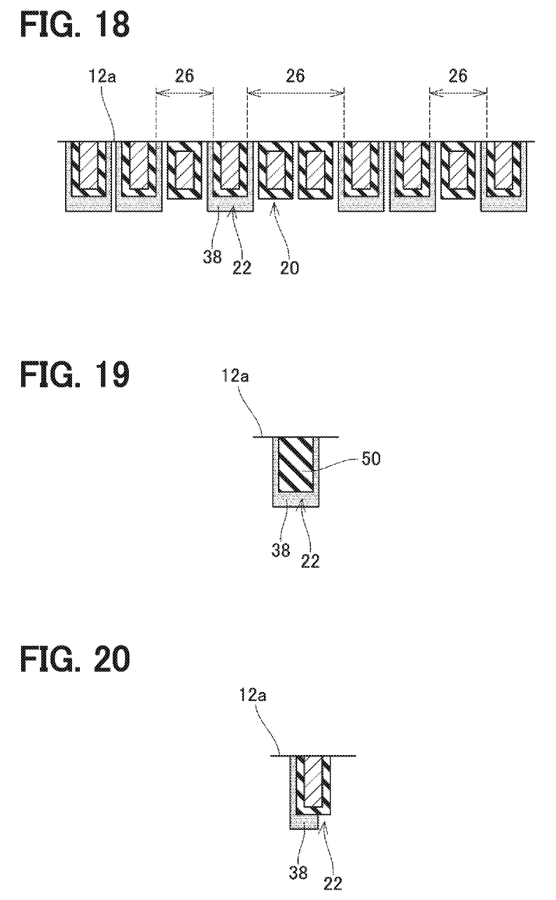

FIGS. 15 to 18 show modifications in the layout pattern of the gate trenches 20 and the dummy trenches 22. In FIG. 15 to 18, only the trench and the connection region 38 are shown, and other parts are not shown. In the first to third embodiments, two gate trenches 20 are arranged in one element region 26. However, as shown in FIG. 15, one gate trench 20 may be disposed in one element region 26. Furthermore, three or more gate trenches 20 may be arranged in one element region 26. The two dummy trenches 22 are arranged in the area between the two element regions 26 in the embodiments, but as shown in FIG. 16, one dummy trench 22 may be arranged between the two element regions 26. Furthermore, three or more dummy trenches 22 may be arranged between two element regions 26. Alternatively, one gate trench 20 and one dummy trench 22 may be alternately arranged as shown in FIG. 17. Furthermore, as shown in FIG. 18, the arrangement pattern of the gate trenches 20 and the dummy trenches 22 may vary depending on the position.

In the embodiments, the insulating film 22a and the dummy electrode 22b are provided in the dummy trench 22. However, as shown in FIG. 19, the dummy trench 22 may be filled with an insulating layer 50. The dummy trench 22 may have another structure while no channel is formed on the side surface.

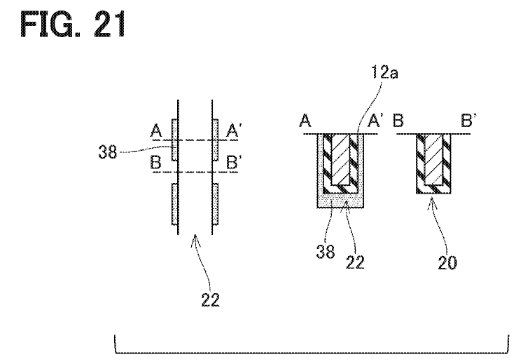

In the embodiments, the connection region 38 is provided to cover the entire side and bottom surfaces of the dummy trench 22, but the connection region 38 may be provided partially relative to the dummy trench 22. For example, as shown in FIG. 20, the connection region 38 may be provided on only one side of the dummy trench 22. Furthermore, as shown in FIG. 21, a portion where the connection region 38 is provided and a portion where the connection region 38 is not provided may be provided alternately in the longitudinal direction of the dummy trench 22 (i.e., the y direction).

In the embodiments, the gate trench 20 and the dummy trench 22 have the same depth, but the gate trench 20 and the dummy trench 22 may have different depths.

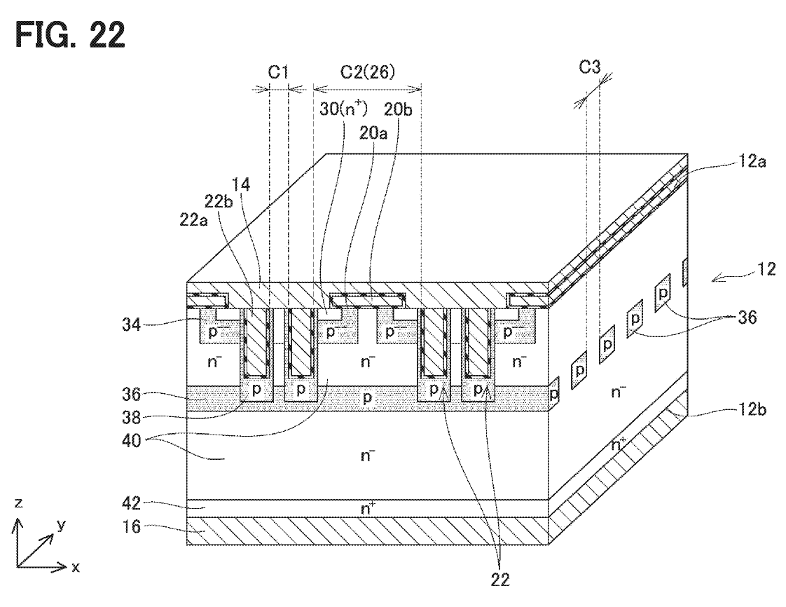

In the embodiments, the trench-type gate electrode 20b is provided in the element region 26. However, as shown in FIG. 22, a planar gate electrode 20b may be provided in the element region 26. In FIG. 22, the gate insulating film 20a is provided to cover the upper surface 12a, and the gate electrode 20b is disposed on the gate insulating film 20a. The source region 30, the body region 34, and the drift region 40 are in contact with the gate insulating film 20a on the upper surface 12a. This structure also makes it possible to prevent an avalanche current from flowing near the gate insulating film 20a, and to prevent deterioration of the gate insulating film 20a.

In the embodiments, the switching element is a MOSFET, but the switching element may be an IGBT. In the MOSFET, the n-type drain region 42 is replaced with a p-type collector region, thereby obtaining the structure of an IGBT. In this case, the source and drain are referred to as the emitter and collector respectively.

In a first configuration, a switching element has: a semiconductor substrate having dummy trenches; a gate insulating film in contact with an element region of the semiconductor substrate between the dummy trenches; a gate electrode in contact with the gate insulating film and insulated from the semiconductor substrate by the gate insulating film; and a source electrode in contact with the element region. The semiconductor substrate has: a first conductivity type source region in contact with the source electrode and the gate insulating film; and a second conductivity type body region arranged within the element region and in contact with the source region and the gate insulating film. A drift region is distributed from within the element region to below the dummy trenches and in contact with the body region and the gate insulating film within the element region. Intermediate regions of second conductivity type extend linearly, within the drift region, in a second direction intersecting the first direction and are arranged at interval in a direction perpendicular to the second direction. The intermediate regions are arranged such that a lower end of each intermediate region is located below a lower end of each dummy trench. A second conductivity type connection region is located adjacent to the dummy trench to connect the intermediate region to the source electrode.

In a second configuration, the switching element may further include a low-concentration intermediate second-conductivity-type region having a lower second-conductivity-type impurity concentration than the intermediate regions and in contact with the intermediate regions from below.

In a third configuration, each of the connection regions has a second-conductivity-type impurity concentration higher than that of each of the low-concentration intermediate second-conductivity-type regions, and a lower end of each of the connection regions is located lower than a lower end of each of the intermediate regions.

In a fourth configuration, a lower end of each of the connection regions is located above a lower end of each of the low-concentration intermediate second-conductivity-type regions.

In a fifth configuration, a gate trench extending in the first direction is provided on the upper surface of the semiconductor substrate in the element region. The gate insulating film covers an inner surface of the gate trench, and the gate electrode is disposed in the gate trench.

In a sixth configuration, the gate trenches are provided at interval in a direction perpendicular to the first direction on the upper surface of the semiconductor substrate in the element region.

In a seventh configuration, a second conductivity type contact region connecting the source electrode and the body region is provided in a portion of the element region between the gate trenches.

In an eighth configuration, an insulating film is disposed in the dummy trench to cover the inner surface of the dummy trench. A dummy electrode is arranged in the dummy trench as insulated from the semiconductor substrate by the insulating film and insulated from the gate electrode.

In a ninth configuration, each of the dummy electrodes is electrically connected to the source electrode.

In a tenth configuration, the drift region is a first conductivity type region.

In an eleventh configuration, the drift region above each of the intermediate regions is a first conductivity type region, and the drift region below each of the intermediate regions has a superjunction structure in which second-conductivity-type regions and first-conductivity-type regions are arranged alternately in a lateral direction.

In a twelfth configuration, a method for manufacturing the switching element includes: forming the dummy trenches on the upper surface of the semiconductor substrate by etching; and forming the connection regions by ion-implanting second conductivity type impurities into side surfaces of the dummy trenches.

In a thirteenth configuration, a method for manufacturing the switching element includes: simultaneously forming the gate trench and the dummy trenches on the upper surface of the semiconductor substrate by etching; and forming the connection regions by ion-implanting second conductivity type impurities into side surfaces of the dummy trenches.

According to the second configuration, the depletion layer spreads in the low-concentration intermediate second-conductivity-type region when the switching element is turned off, thereby improving the breakdown voltage of the switching element.

According to the third configuration, the electric field tends to concentrate near the bottom end of the connection region more easily than in the surrounding area, so that an avalanche current tends to occur near the bottom end of the connection region. This limits the path through which the avalanche current flows to the vicinity of the connection region, thereby more effectively restricting the deterioration of the gate insulating film.

According to the fourth configuration, the connection region can be prevented from being depleted, thereby restricting leakage current.

According to the fifth aspect, the electric field applied to the gate insulating film covering the lower end of the gate trench can be reduced by the intermediate region.

According to the seventh configuration, the potential of the body region can be stabilized.

According to the ninth aspect, the potential of the dummy trench can be stabilized.

According to the eleventh configuration, the withstand voltage of the switching element can be improved.

According to the twelfth aspect, the connection region can be easily formed.

According to the thirteenth aspect, the gate trench and the dummy trench can be formed efficiently.

Although the embodiments have been described in detail above, these are merely examples and do not limit the scope of present disclosure. The techniques described in claims include various modifications of the specific examples illustrated above. The technical elements described in the present specification or the drawings exhibit technical usefulness alone or in various combinations, and are not limited to the combinations described in the claims at the time of filing. In addition, the techniques illustrated in the present specification or drawings achieve plural objectives at the same time, and achieving one of the objectives itself has technical usefulness.

What is claimed is:

1. A switching element comprising:
a semiconductor substrate having a plurality of dummy trenches extending in a first direction on an upper surface, the plurality of dummy trenches being arranged at interval in a direction perpendicular to the first direction;
a gate insulating film in contact with an element region of the semiconductor substrate between the plurality of dummy trenches;
a gate electrode in contact with the gate insulating film and insulated from the semiconductor substrate by the gate insulating film; and
a source electrode in contact with the element region, wherein
the semiconductor substrate includes:
a source region of a first conductivity type located in the element region and in contact with the source electrode and the gate insulating film;
a body region of a second conductivity type located in the element region and in contact with the source region and the gate insulating film;
a drift region distributed from within the element region to below each of the plurality of dummy trenches and in contact with the body region and the gate insulating film within the element region;
a plurality of intermediate regions of a second conductivity type extending linearly within the drift region in a second direction intersecting the first direction and arranged at interval in a direction perpendicular to the second direction, a lower end of each of the plurality of intermediate regions being located lower than a lower end of each of the plurality of dummy trenches; and
a plurality of connection regions of a second conductivity type respectively located adjacent to the plurality of dummy trenches to connect the plurality of intermediate regions to the source electrode.

2. The switching element according to claim 1, further comprising: a low-concentration region of a second conductivity type having a second conductivity type impurity concentration lower than that of the plurality of intermediate regions and in contact with the plurality of intermediate regions from below.

3. The switching element according to claim 2, wherein
each of the connection regions has a second conductivity type impurity concentration higher than that of the low-concentration region, and
a lower end of each of the connection regions is located lower than a lower end of each of the intermediate regions.

4. The switching element according to claim 3, wherein a lower end of each of the connection regions is located above a lower end of the low-concentration region.

5. The switching element according to claim 1, wherein
a gate trench extends in the first direction on the upper surface of the semiconductor substrate within the element region,
the gate insulating film covers an inner surface of the gate trench, and
the gate electrode is disposed in the gate trench.

6. The switching element according to claim 5, wherein the gate trench is one of a plurality of gate trenches arranged at interval in a direction perpendicular to the first direction on the upper surface of the semiconductor substrate within the element region.

7. The switching element according to claim 6, wherein a contact region of a second conductivity type connects the source electrode and the body region with each other within a portion of the element region between the plurality of gate trenches.

8. The switching element according to claim 1, further comprising:
an insulating film covering an inner surface of the dummy trench within each of the dummy trenches; and
a dummy electrode insulated from the semiconductor substrate by the insulating film and insulated from the gate electrode within each of the dummy trenches.

9. The switching element according to claim 8, wherein the dummy electrode is electrically connected to the source electrode.

10. The switching element according to claim 1, wherein the drift region is a first conductivity type region.

11. The switching element according to claim 1, wherein
the drift region located above each of the intermediate regions is a first conductivity type region, and
the drift region located below each of the intermediate regions has a superjunction structure in which second conductivity type regions and first conductivity type regions are alternately arranged in a lateral direction.

12. A manufacturing method of the switching element according to claim 1 comprising:
forming the plurality of dummy trenches on the upper surface of the semiconductor substrate by etching; and
forming the plurality of connection regions by ion-implanting a second conductivity type impurity into side surfaces of the dummy trenches.

13. A manufacturing method of the switching element according to claim 5 comprising:
simultaneously forming the gate trench and the plurality of dummy trenches on the upper surface of the semiconductor substrate by etching; and
forming the plurality of connection regions by ion-implanting a second conductivity type impurity into side surfaces of the dummy trenches.
